(19) United States
(12) Patent Application Publication
(10) Pub. No.: US 2008/0296711 A1
(43) Pub. Date: Dec. 4, 2008

(54) MAGNETOELECTRONIC DEVICE HAVING ENHANCED PERMEABILITY DIELECTRIC AND METHOD OF MANUFACTURE

(75) Inventors: Kelly W. Kyler, Mesa, AZ (US); Kerry J. Nagel, Phoenix, AZ (US); Piyush M. Shah, Mesa, AZ (US)

Correspondence Address: MESCHKOW & GRESHAM, P.L.C., 5727 NORTH SEVENTH STREET, SUITE 409, PHOENIX, AZ, 85014, US

(73) Assignee: Freescale Semiconductor, Inc., Austin, TX (US)

(21) Appl. No.: 11/755,498

(22) Filed: May 30, 2007

(51) Int. Cl. H01L 29/82; H01L 21/8246

(52) U.S. Cl. 257/421; 438/3; 257/E29.323; 257/E21.665

(57) ABSTRACT

A magnetoelectronic device structure 20 includes programming lines 26 and 28 and a magnetoelectronic device 24 between the programming lines 26 and 28. In one embodiment, layers 38, 40, and 42 of a colloidal dispersion of an electrically insulating material and magnetic particles are positioned between the magnetoelectronic device 24 and the programming lines 26 and 28. The magnetic particles cause the colloidal dispersion to have an enhanced magnetic permeability property. The layers 38, 40, and 42 are disposed by a spin coating technique.

### TECHNICAL FIELD OF THE INVENTION

The present invention relates generally to magnetoelectronic devices. More specifically, the present invention relates to low power magnetoelectronic devices that utilize enhanced permeability materials.

### BACKGROUND OF THE INVENTION

Magnetoelectronics, spin electronics and spintronics are synonymous terms for the use of effects predominantly caused by electron spin. Magnetoelectronics is used in numerous information devices, and provides non-volatile, reliable, radiation resistant, and high-density data storage and retrieval. The numerous magnetoelectronic information devices include, but are not limited to, Magnetoresistive Random Access Memory (MRAM), magnetic sensors, and read/write heads and hard disks for disk drives.

A magnetoelectronic information device, such as an MRAM, typically includes an array of magnetoresistive memory elements. Each magnetoresistive memory element typically has a structure that includes multiple magnetic layers separated by various non-magnetic layers. Information is stored as directions of magnetization vectors in the magnetic layers. Magnetic vectors in one magnetic layer are magnetically fixed or pinned, while the magnetization direction of another magnetic layer is free to switch between the same and opposite directions that are called “parallel” and “antiparallel” states, respectively. In response to parallel and antiparallel states, the magnetoresistive memory element represents two different resistances. The measured resistance of the magnetoresistive memory element has minimum and maximum values when the magnetization vectors of the two magnetic layers point in substantially the same and opposite directions, respectively. Accordingly, a detection of change in the measured resistance allows a magnetoelectronic information device, such as an MRAM device, to provide information stored in the magnetoresistive memory element.

Typically, a magnetoresistive memory element is programmed by a magnetic field created by current flowing through one or more conductors, or programming lines, disposed proximate the memory element. To program the magnetoresistive memory element, the magnetic field applied by the programming line is of sufficient magnitude to switch the direction of the magnetic vectors of one or more magnetic layers of the memory element.

There is an ever-increasing demand for smaller and lower power memory devices. Accordingly, it is desirable to provide a magnetoelectronic device structure that requires low power for programming. In addition, it is desirable to provide an magnetoelectronic device structure in which the current required to program a magnetoresistive memory element of the magnetoelectronic device structure is reduced. It also is desirable to provide a method for fabricating an magnetoelectronic device structure that is cost effective and is readily manufactured.

### BRIEF DESCRIPTION OF THE DRAWINGS

A more complete understanding of the present invention may be derived by referring to the detailed description and claims when considered in connection with the Figures, wherein like reference numbers refer to similar items throughout the Figures, and:

FIG. 1 shows a cross-sectional view of a magnetoelectronic device structure in accordance with an exemplary embodiment of the invention; and

FIG. 2 shows a flowchart of a fabrication process for making the magnetoelectronic device structure in accordance with another exemplary embodiment of the invention.

### DETAILED DESCRIPTION

In one embodiment of the invention, a magnetoelectronic device structure includes multiple layers of a colloidal dispersion, deposited one layer at a time. The colloidal dispersion includes an electrically insulating material, such as a liquid spin-on dielectric material, with dispersed magnetic particles. In another embodiment of the invention, a method of making a magnetoelectronic device structure includes dispensing a colloidal dispersion of an electrically insulating material and magnetic particles using a spin coating technique. Magnetic material in the colloidal dispersion increases the magnetic permeability of the electrically insulating material. In the case of a magnetoelectronic memory element such as a Magnetoresistive Random Access Memory (MRAM), the increased magnetic permeability can reduce the required write current, thus lowering the power required for operation. In the case of other magnetoelectronic devices such as inductors, transformers, and magnetic sensors, the increased magnetic permeability can improve device performance by increasing magnetic coupling. The following description of the invention is exemplary in nature and is not intended to limit the invention.

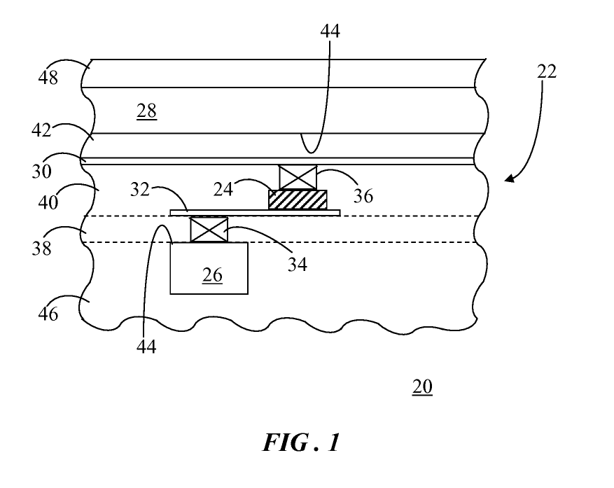

FIG. 1 shows a cross-sectional view of a magnetoelectronic device structure 20 in accordance with an exemplary embodiment of the invention. Magnetoelectronic device structure 20 includes a magnetoelectronic device 22. In the illustrated embodiment, magnetoelectronic device 22 is a magnetoresistive memory cell. However, in alternative embodiments, magnetoelectronic device 22 may be a passive device such as an inductor or transformer, a magnetic sensor, or the like.

Magnetoelectronic device 22 includes a magnetoresistive memory element 24, which may comprise, for example, a magnetic tunnel junction (MTJ) device or a giant magnetoresistive (GMR) device. Magnetoelectronic device 22 further includes a conductive programming line, referred to herein as a digit line 26, disposed below magnetoresistive memory element 24 and another conductive programming line, referred to herein as a bit line 28. Bit line 28 is disposed above magnetoresistive memory element 24 and is arranged orthogonal to digit line 26. While for discussion purposes digit line 26 is illustrated in FIG. 1 below magnetoresistive memory element 24 and bit line 28 is illustrated in FIG. 1 above magnetoresistive memory element 24, it should be understood that the opposite positioning may also be utilized, that is, bit line 28 may be disposed underlying magnetoresistive memory element 24 and digit line 26 may be disposed overlying magnetoresistive memory element 24.

Magnetoelectronic device 22 further includes a top electrode 30, a bottom electrode 32, and vias 34 and 36. Top electrode 30 may be disposed overlying magnetoresistive memory element 24, and bottom electrode 32 may be disposed underlying magnetoresistive memory element 24. In addition, magnetoelectronic device structure 20 includes material layers 38, 40, and 42. Layer 38 is disposed between digit line 26 and bottom electrode 32. Layer 40 is disposed between bottom electrode 32 and top electrode 30, and layer 42 is disposed between top electrode 30 and bit line 28. Those skilled in the art will recognize that bit line 28 may function as top electrode 30. If such is the case, layer 42 may not be required. Layers 38, 40, and 42 are formed from a colloidal dispersion of an electrically insulating material and magnetic particles. Thus, layers 38, 40, and 42 yield an interlayer dielectric with enhanced magnetic permeability.

The term “colloidal dispersion” refers to a mixture containing particles larger than those found in a solution but small enough to remain suspended for a very long time. Typically, the size of dispersed phase particles in a colloidal dispersion ranges from approximately one nanometer to approximately one micrometer.

The electrically insulating material within the colloidal dispersion of material layers 38, 40, and 42 is a dielectric material, and more particularly, a flowable dielectric. In one embodiment, the flowable dielectric may be a spin-on material or spin-on glass formulation. A spin-on glass formulation is typically a liquid, silicon-based composition that can be applied to the surface of a substrate, such as in the various layers of magnetoelectronic device structure 20, and spun with structure 20 to provide a coating, preferably with a level top surface. With this technique, the spin-on glass formulation can fill in any valleys or recessed areas in the surface of structure 20 that result from the various insulating and conductive regions. The spin-on glass flowable liquid source is then dried to form a solid layer which can be cured at an appropriate temperature to form a dielectric film, or layer. Although spin-on glass is discussed herein, in an alternate embodiment, the spin-on dielectric may be a polyimide formulation or another material that can be applied by a spin-on process to become a dielectric film.

The magnetic particles within the colloidal dispersion of material layers 38, 40, and 42 may be magnetic nanoparticles of iron, cobalt, nickel, or alloys thereof. Other magnetic particles may include mu-metal, and nanoparticles of manganese, magnesium, or their alloys. The colloidal dispersion of electrically insulating material and magnetic particles may be formed by mixing, doping, or otherwise incorporating the magnetic particles into the flowable dielectric to yield a uniform distribution of the magnetic particles within the flowable dielectric. A concentration of magnetic particles within the flowable dielectric may be between approximately twenty-five and approximately thirty percent of the magnetic particles relative to the flowable dielectric. This concentration can produce an enhanced permeability property for the flowable dielectric in a range from approximately two to approximately one hundred. In one embodiment, each of layers 38, 40, and 42 have an equivalent concentration of magnetic particles. However, in alternate embodiments, layers 38, 40, and 42 may have different concentrations of magnetic particles in accordance with a desired permeability property for each of layers 38, 40, and 42.

Typical non-ferromagnetic materials, including flowable dielectrics, have a magnetic permeability that is approximately equal to one. The magnetic permeability of the flowable dielectric is increased above one within layers 38, 40, and 42, through the addition of magnetic particles within the flowable dielectric. By increasing the permeability of layers 38, 40, and 42, the magnetic field generated at electromagnetic device 22 may be increased without a commensurate increase in the write current through bit line 28. Accordingly, by using layers 38, 40, and 42 having an “enhanced permeability,” that is, a permeability greater than about one, a lower current may be required to produce the magnetic field. In this manner, a low power magnetoresistive memory element 24 may be fabricated. For other magnetic devices, the increased permeability of the interlayer dielectric improves device performance in increasing magnetic coupling.

Colloidal particles, such as the magnetic particles that may be used to form the colloidal dispersion, often carry an electrical charge and therefore can attract or repel each other. Unstable colloidal dispersions can form floc, or clumps of particles, as the particles aggregate due to interparticle attractions. Such a situation is undesirable in layers 38, 40, and 42 because excessive clumping of magnetic particles within the dielectric layers 38, 40, and 42 can cause localized areas of conductivity which can compromise the function and reliability of magnetoelectronic device 22. Accordingly, the magnetic particles of the colloidal dispersion may be passivated or otherwise stabilized so that the magnetic particles are made “passive” in relation to one another. Passivation entails the formation of a thin adherent film or layer on the surface of a metal or mineral, such as magnetic particles, that acts as a protective coating to protect the underlying surface from further chemical reaction. The passive film is often, though not always, an oxide. If the magnetic particles are passivated or otherwise stabilized prior to forming the colloidal dispersion, the magnetic particles will be less likely to aggregate, or clump, within the colloidal dispersion thereby preventing the formation of localized areas of conductivity within dielectric layers 38, 40, and 42.

Both digit line 26 and bit line 28 may be surrounded at all surfaces except surfaces 44 most proximate magnetoresistive memory element 24 by ferromagnetic cladding layers (not shown), as is known in the art. As such, it is not necessary to have materials with enhanced permeability disposed about the cladded surfaces of digit line 26 and bit line 28. However, it should be appreciated that in the absence of cladding layers, a material layer 46 disposed about digit line 26 and another material layer 48 disposed about bit line 28 may exhibit enhanced permeability.

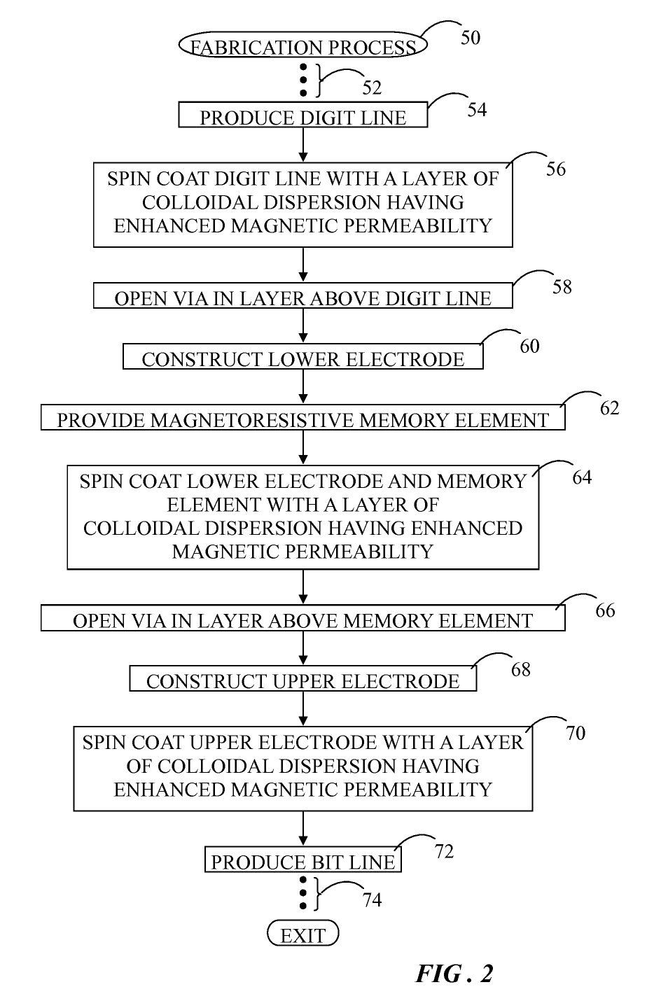

FIG. 2 shows a flowchart of a fabrication process 50 for making a magnetoelectronic device structure, such as magnetoelectronic device structure 20 of FIG. 1, in accordance with another exemplary embodiment of the invention. For sake of convenience, fabrication process 50 will be described with reference to a magnetoelectronic device structure in which a conductive programming line is fabricated below a magnetoresistive memory element and another conductive programming line is fabricated above a magnetoelectronic memory element with layers of the enhanced permeability colloidal dispersion disposed between them. However, it should be appreciated that fabrication process 50 is not so limited, and may be utilized to fabricate a magnetoelectronic device structure comprising a magnetoresistive memory element disposed along side of the programming lines, with enhanced permeability colloidal dispersion disposed adjacent to the magnetoresistive memory element and/or the programming lines.

Fabrication process 50 is described in terms of the fabrication of magnetoelectronic device structure 20 (FIG. 1) of a single magnetoelectronic device 22 containing a single magnetoresistive memory element 24. However, it should be readily apparent that the following discussion applies equivalently to a substrate upon which multiple magnetoelectronic devices 22 are fabricated concurrently to make up, for example, a magnetoresistive random access memory (MRAM).

Fabrication process 50 commences with ellipses 52. Ellipses 52 refer to an omission of operations in the fabrication of the underlying elements of magnetoelectronic device structure 20, which are fabricated in accordance with known methodologies. Accordingly, only that portion of fabrication process 50 for fabricating magnetoelectronic device structure 20 is discussed below.

Fabrication process 50 continues with a task 54. At task 54, digit line 26 (FIG. 1) is produced. Digit line 26 may be formed, for example, by damascene or other similar processes in which digital line 26 is formed within material layer 46. Alternatively, conductive material may be formed on a substrate and suitably etched to produce digital line 26, as known to those skilled in the art. Following formation of digit line 26 at task 54, a task 56 is performed.

At task 56, digit line 26 and any underlying materials and structures, such as material layer 46 (FIG. 1), are spin coated with colloidal dispersion of the flowable liquid source and magnetic materials to form layer 38 (FIG. 1). Spin coating refers to a procedure used to apply uniform thin films to a substrate using a machine known as a spin coater, or simply a coater. In accordance with task 56, the colloidal dispersion, with or without a solvent, is dispensed on the substrate, in this case on digit line 26 and material layer 46. The substrate is rotated at high speed in order to spread the fluid by centrifugal force. Rotation is typically continued while the fluid spins off the edges of the substrate, until the desired thickness of the film, in this case layer 38, is achieved. The thickness of the film depends on the spin speed, i.e., the higher the spin speed, the thinner the film. In response to spin coating task 56, the colloidal dispersion in the form of layer 38 having enhanced magnetic permeability is deposited over digit line 26 and any other underlying materials and structures.

Following task 56, a task 58 is performed. At task 58, via 34 (FIG. 1) is opened in layer 38 above digit line 26 utilizing known fabrication techniques.

Next, a task 60 is performed. At task 60, bottom electrode 32 (FIG. 1) is constructed utilizing known fabrication techniques, such as deposition, photolithography, wet and dry etching and micromachining, and the like.

Fabrication process 50 continues with a task 62. At task 62, magnetoresistive memory element 24 (FIG. 1) is provided. As known to those skilled in the art, magnetoresistive memory element 24, also known as a magnetic tunnel junction, comprises a stack of thin films in which at least two are ferromagnetic, and which are separated by a thin insulating layer in a “sandwich” construction. The thin insulating layer, or dielectric, acts as a tunnel barrier. Provision of magnetoresistive memory element 24 may be achieved through its formation on bottom electrode 32 by any suitable methods or practice known in the semiconductor industry.

Following task 62, a task 64 is performed. At task 64, magnetoresistive memory element 24 and any exposed portion of lower electrode 32 are spin coated with colloidal dispersion of flowable dielectric and magnetic materials to form layer 40 (FIG. 1) having enhanced magnetic permeability. Accordingly, layer 40 overlies magnetoresistive memory element 24 and any exposed portion of lower electrode 32.

Next, a task 66 is performed. At task 66, via 36 (FIG. 1) is opened in layer 40 above magnetoresistive memory element 24 utilizing known fabrication techniques.

Following task 66, a task 68 is performed. At task 68, top electrode 30 (FIG. 1) is constructed by any suitable methods or practice known in the semiconductor industry. [0030] Fabrication process 50 continues with a task 70. At task 70, top electrode 30 is spin coated with colloidal dispersion of flowable dielectric and magnetic materials to form layer 42 (FIG. 1) having enhanced magnetic permeability. Accordingly, layer 42 overlies top electrode 30. Those skilled in the art will recognize that bit line 28 may function as top electrode 30. If such is the case, layer 42 of the colloidal dispersion may not be required and task 70 would not be performed.

Next, a task 72 is performed to produce another conductive programming line, in this embodiment, bit line 28 (FIG. 1). Bit line 28 is constructed by any suitable methods or practice known in the semiconductor industry. Following the execution of task 72, that portion of fabrication process 50 pertinent to the construction of magnetoelectronic device structure 20 (FIG. 1) is complete. However, ellipses 74 are included in process 50 after task 72 to indicate an omission of any remaining fabrication operations, such as application of material layer 48 (FIG. 1), and so forth in accordance with known methodologies. Fabrication process 50 exits following those remaining fabrication operations.

A magnetoelectronic device structure that utilizes enhanced permeability dielectric material disposed between a magnetoresistive memory element and programming lines has been described. The enhanced dielectric material is a colloidal dispersion of a flowable dielectric material and magnetic particles. The colloidal dispersion is dispensed using a spin coating technique. Magnetic material in the colloidal dispersion increases the magnetic permeability of the dielectric material. In the case of a magnetoelectronic memory element such as a Magnetoresistive Random Access Memory (MRAM), the increased magnetic permeability can reduce the required write current, thus lower the power required for operation. In the case of other magnetoelectronic devices such as inductors, transformers, and magnetic sensors, the increased magnetic permeability can improve device performance by increasing magnetic coupling. The application of an increased permeability spin-on material, using a known spin coating technique and existing spin-on tooling, increases manufacturing efficiencies and commensurately decreases manufacturing costs.

Although an embodiment of the invention has illustrated and described in detail, it will be readily apparent to those skilled in the art that various modifications may be made therein without departing from the spirit of the invention or from the scope of the appended claims.

What is claimed is:

1. A method for making a magnetoelectronic device structure comprising:
providing a magnetoelectronic device;
forming a colloidal dispersion of an electrically insulating material and magnetic particles, said magnetic particles causing said colloidal dispersion to have an enhanced magnetic permeability property; and
spin coating said colloidal dispersion adjacent said magnetoelectronic device.

2. A method as claimed in claim 1 further comprising utilizing a liquid source to form a dielectric film as said electrically insulating material.

3. A method as claimed in claim 2 further comprising selecting a spin-on dielectric formulation for said liquid source.

4. A method as claimed in claim 1 wherein said forming operation comprises uniformly distributing said magnetic particles in said electrically insulating material.

5. A method as claimed in claim 1 further comprising selecting said magnetic particles from a group consisting of iron, cobalt, nickel, and alloys thereof.

6. A method as claimed in claim 1 further comprising utilizing said magnetic particles having a passivated surface.

7. A method as claimed in claim 1 further comprising utilizing magnetic nanoparticles as said magnetic particles.

8. A method as claimed in claim 1 wherein said forming operation comprises producing said colloidal dispersion to include a concentration that is between approximately twenty-five and approximately thirty percent of said magnetic particles relative in said electrically insulating material.

9. A method as claimed in claim 1 wherein:
said method further comprises producing a programming line; and
said spin coating operation includes disposing a first layer of said colloidal dispersion between said programming line and said magnetoelectronic device.

10. A method as claimed in claim 9 wherein said programming line is a first programming line underlying said magnetoelectronic device, and said method further comprises:
disposing a second layer of said colloidal dispersion over said magnetoelectronic device; and
producing a second programming line overlying said second layer of said colloidal dispersion.

11. A magnetoelectronic device structure comprising:
a first programming line;
a second programming line;
a magnetoelectronic device between said first and second programming lines; and
a colloidal dispersion of an electrically insulating material and magnetic particles positioned between said first programming line and said magnetoelectronic device and between said magnetoelectronic device and said second programming line, said magnetic particles causing said colloidal dispersion to have an enhanced magnetic permeability property.

12. A structure as claimed in claim 11 wherein said electrically insulating material comprises a spin-on dielectric formulation.

13. A structure as claimed in claim 11 wherein said magnetic particles comprise magnetic nanoparticles.

14. A structure as claimed in claim 11 wherein said magnetic particles comprise passivated magnetic particles.

15. A structure as claimed in claim 11 wherein said magnetic particles are selected from a group consisting of iron, cobalt, nickel, and alloys thereof.

16. A structure as claimed in claim 11 wherein said colloidal dispersion comprises a concentration of said magnetic particles of between approximately twenty-five and approximately thirty percent of said magnetic particles relative in said electrically insulating material.

17. A method for making a magnetoelectronic device structure comprising:
providing a magnetoelectronic device;
forming a colloidal dispersion that includes a dielectric material and magnetic particles by uniformly distributing said magnetic particles in a liquid source used to form said dielectric material, said magnetic particles causing said colloidal dispersion to have an enhanced magnetic permeability property; and
spin coating said colloidal dispersion adjacent said magnetoelectronic device.

18. A method as claimed in claim 17 further comprising selecting a spin-on glass formulation for said liquid source.

19. A method as claimed in claim 17 further comprising utilizing said magnetic particles having a passivated surface.

20. A method as claimed in claim 17 wherein said spin coating comprises spin coating more than one layer of colloidal dispersion wherein said more than one layer includes different concentrations of magnetic particles corresponding to a desired permeability property for each said layer.
